(19) United States
(12) Patent Application Publication
(10) Pub. No.: US 2003/0140961 A1
(43) Pub. Date: Jul. 31, 2003

(54) Electric energy production and sun protection device for motor vehicles

(76) Inventors: Daniel Damson, Weissach-Flacht (DE); Ekkehard Laqua, Oberhausen (DE)

Correspondence Address: KENYON & KENYON, ONE BROADWAY, NEW YORK, NY, 10004, US

(21) Appl. No.: 10/220,215

(22) PCT Filed: Dec. 15, 2001
(86) PCT No.: PCT/DE01/04753

(30) Foreign Application Priority Data
Dec. 28, 2000 (DE) 100 65 530.0

(51) Int. Cl. H01L 31/00

(52) U.S. Cl. 136/244; 136/291

(57) ABSTRACT

Device for generating power and providing shade in motor vehicles. A solar cell (1) having a reflective back surface layer is attached to a suitable body part (2) of a motor vehicle. An insulating and inner lining layer (3) is provided beneath the body part, which may be, for example, the body sheet of the roof of a vehicle. The solar cell mainly includes a supporting layer (11), a reflective layer (12) on the back of an active photovoltaic layer (13) and a protective layer (14) that covers the latter in an upward direction, i.e., toward the outside, in the direction of the incident radiation. The incident radiation, sunlight or daylight, is represented by the row of arrows (4), and the radiation reflected at the boundary between the photovoltaic layer and the reflective layer is represented by the two arrows (5). The total reflected radiation is represented by the five arrows (6) and includes the component reflected at the boundary between the photovoltaic layer and the reflective layer and leaving the photovoltaic layer, and the components reflected at the surface of the protective layer itself and also at the boundary layer between the protective layer 14 and the photovoltaic layer 13. Thin-film solar cells or transparent solar cells may be provided as further implementations.

### BACKGROUND INFORMATION

The present invention relates to a device for generating power and pr vehicles according to the definition of the species in the preamble of

A method for the direct, power-optimized matching of a solar generator to the motor of a production vehicle fan, in which the solar generator is matched to the motor by a DC/DC step-down converter, is known from German Patent Application 40 17 670 A1. The solar generator may be integrated into the sun roof of a motor vehicle. According to this known related art, a general supply of the power generated by the solar generator to the vehicle electrical system and intentional shading of important motor vehicle parts are neither intended nor expressly provided.

### ADVANTAGES OF THE PRESENT INVENTION

The device according to the present invention for generating power and providing shade in motor vehicles, having the characterizing features of Claim 1, has the advantage over the related art that solar cells provide shade for important motor vehicle parts, thus lowering the temperature to which they are exposed, while simultaneously generating power that is supplied to the vehicle electrical system, i.e., the battery. This is possible, in particular, while the vehicle is at a standstill so that power is generated in the presence of sunlight or daylight and heating up of the vehicle is also reduced. If necessary, the energy that the air conditioning system requires to cool the vehicle may also be reduced.

According to the present invention, this object is achieved in principle by providing solar cells as separate or integrated components on suitable vehicle body parts and connecting them to loads, i.e., the vehicle battery, for the purpose of supplying the generated electrical power.

The features illustrated in the dependent claims are advantageous embodiments, refinements and improvements of the device described in Claim 1.

According to a first advantageous embodiment of the device according to the present invention, solar cells having a reflective back surface layer or an internal reflective layer are provided as solar cells. According to an advantageous refinement of this device according to the present invention, the solar cells having a reflective back surface layer or an internal reflective layer are designed as semiconductor, in particular, silicon semiconductor solar cells.

Solar cells of this type that are provided with a reflective back surface layer or an internal reflective layer are known per se and used, for example, in aerospace engineering. An article entitled “TPV CELLS WITH HIGH BSR,” by P. A. Iles and C. L. Chu, published in The Second NREL Conference on Thermophotovoltaic Generation of Electricity, AIP Conference Proceedings 358, Woodberg, N.Y., 1996, pages 361-371, describes different designs and materials, indicating that solar cells of this type appear to yield a high efficiency. A further article entitled “Optical Properties of Thin Semiconductor Device Structures with Reflective Back Surface Layers,” by M. B. Clevenger, C. S. Murray, S. A. Ringel, R. N. Sacks, L. Qin, G. W. Charache and D. M. Depoy, published in Thermovoltaic Generation of Electricity, Fourth NREL Conference, AIP Conference Proceedings 460, New York, 1999, pages 327-334, describes improvements in the efficiency of thermovoltaic cells. Neither article describes a use and/or application of such cells in connection with power generation and shading in motor vehicles, nor do they make such a use and/or application obvious.

According to an advantageous refinement of the first embodiment of the present invention, the solar cells are provided on a supporting layer, and the supporting layer is permanently connected to a suitable vehicle body part, in particular, to the vehicle roof. According to an advantageous refinement, the supporting layer of the solar cells may be rigid or flexible.

According to a second advantageous embodiment of the device according to the present invention, thin-film solar cells are provided as solar cells, and these thin-film solar cells are integratively deposited and produced on suitable supporting layers or directly on vehicle body parts, in particular, on the vehicle roof.

According to an advantageous refinement of this second embodiment of the device according to the present invention, the thin-film solar cell is designed as a CIS solar cell, the term CIS representing the elements copper, indium and selenium from which the photovoltaically active absorber layer is made.

In keeping with the preferred applications of the present invention, the thin-film solar cells are provided, according to an advantageous refinement, with a protective layer that is visually coordinated with the vehicle paintwork. The solar cells are thus visually integrated into the vehicle design.

According to a third advantageous embodiment of the device according to the present invention, transparent solar cells are provided as solar cells.

According to an especially suitable refinement of this third embodiment of the device according to the present invention, the transparent solar cells are embedded in glass. According to an advantageous refinement, the transparent solar cells are provided on windows of the vehicle or integrated into a window by providing them between two window panes. According to a suitable refinement, the transparent solar cells may be attached to side windows and/or rear windows and/or the upper area of the windshield, in particular, to the inside thereof.

According to an advantageous and suitable refinement of this third embodiment of the device according to the present invention, POWER solar cells (POWER stands for Polycrystalline Wafer Engineering Result) are provided as transparent solar cells into which tiny holes are incorporated by machining the base material, in particular silicon, making the solar cells transparent.

### DRAWING

The present invention is explained in greater detail in the following description on the basis of exemplary embodiments and implementation examples illustrated in the drawing, in which:

FIG. 1 shows a schematic, cross-sectional representation of a first implementation of the present invention, using a solar cell that is provided with a reflective back surface layer and is attached to a suitable part of a motor vehicle body; the schematicized irradiation and reflection ratios are also shown;

FIG. 2 shows a schematic representation of the reflectivity of silicon semiconductor solar cells as a function of wavelength λ of the incident radiation;

FIG. 3 shows a schematic representation of the structure of a CIS thin-film solar cell that, according to the present invention, may be used in a second embodiment of the present invention;

FIG. 4 shows a schematic representation of steps involved in manufacturing a CIS thin-film solar cell according to FIG. 4; and

FIG. 5 shows a schematic representation of the structure of a transparent solar cell that is provided according to a third embodiment of the present invention.

### DESCRIPTION OF THE EXEMPLARY EMBODIMENTS

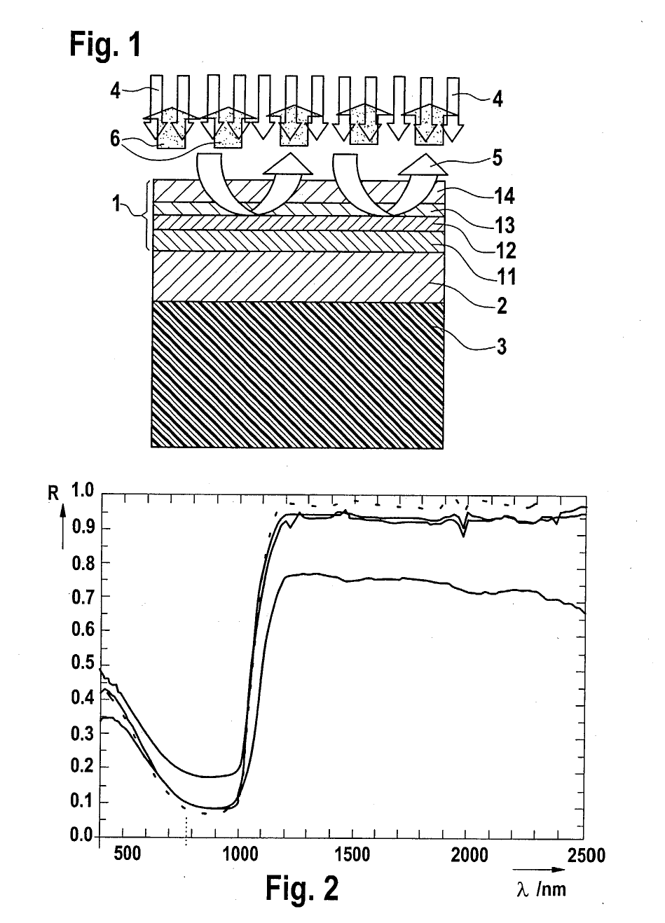

FIG. 1 shows a schematic, cross-sectional representation of a first implementation of the present invention. According to this embodiment of the present invention, a solar cell 1 having a reflective back surface layer is attached to a suitable body part 2 of a motor vehicle. An insulating and possibly inner lining layer 3 may be provided beneath body part 2, which may be, for example, the body sheet of the roof of a motor vehicle that is not illustrated in further detail. Viewed from bottom to top in FIG. 1, solar cell 1 mainly includes a supporting layer 11, a reflective layer 12 on the back of an active photovoltaic layer 13 and a protective layer 14 that covers the latter in an upward direction, i.e., toward the outside, in the direction of the incident radiation. The incident radiation, sunlight or daylight, is represented by a row of downward facing arrows 4, and the radiation reflected at the boundary between photovoltaic layer 13 and reflective layer 12 is represented by the two upward curving arrows 5. The total reflected radiation is represented by five arrows 6 and includes the component mentioned above reflected at the boundary between photovoltaic layer 13 and reflective layer 12 and leaving photovoltaic layer 13, as shown by two arrows 5, and the components reflected at the surface of protective layer 14 itself and also at the boundary layer between protective layer 14 and photovoltaic layer 13.

Reflective layer 12 is a reflective back surface layer of photovoltaic layer 13. Radiant energy that is incident upon photovoltaic layer 13, where it is not converted to electrical energy, i.e., current, is reflected according to two arrows 5. This heats photovoltaic layer 13 and thus also entire solar cell 1, while its underlying structure, such as supporting layer 11 and body part 2, are exposed to lower temperatures. In this manner, the object of the present invention, namely to reduce the heat transferred to vehicles by providing shade or reflection of unconverted incident sunlight, while simultaneously improving the generation of power for the vehicle electrical system, is achieved in a sustained manner. The preferred surface for such solar cells, as shown in FIG. 1, is the vehicle roof.

Conventional solar cells absorb light within a typical frequency range and convert it to electrical energy. A large portion of the radiation heats the solar cells and supporting material. This decreases solar cell efficiency and heats up the supporting material, e.g., the vehicle roof, and thus the vehicle interior. The effect described above is avoided by providing solar cells 1 having a reflective back surface layer according to the present invention. In addition to the radiation that is converted from light to power directly in photovoltaic layer 13, a further portion of the incident radiation is converted there from thermal energy to electrical energy. The radiation component that is unable to be converted to electrical energy is reflected at reflective layer 12 and therefore does not heat up supporting layer 11 and underlying body part 2, for example, the vehicle roof. This reduces the heat transferred to the vehicle, and the efficiency of solar cell 1 does not decrease, since the latter is subject to less heating. Because less heat is transferred to the vehicle, the temperature inside the vehicle is also lower. This increases comfort and possibly also reduces both the energy required by the air conditioner for cooling and the associated energy costs. The electrical energy that is generated at the same time, even when the vehicle is at a standstill, is supplied to the vehicle electrical system. This reduces the amount of fuel needed to meet the vehicle's electrical energy needs.

Solar cell 1 and its supporting layer 11 are permanently connected to underlying body part 2, as necessary. Supporting layer 11 may be intrinsically rigid, or it may be flexible, so as to better match the shape of body part 2. The permanent bond between supporting layer 11 and body part 2 may be established by gluing, for example.

FIG. 2 shows a schematic representation of the reflectivity of silicon semiconductor solar cells, reflection R being dependent on wavelength λ of the incident radiation. The three different curves represent examples of different reflective silicon semiconductor solar cells. Wavelength λ is indicated in nm. The visible range of incident radiation is more or less below a wavelength of around 780 nm, while the infrared range is above it. The illustrated spectral characteristic curves show that reflection R is lower in the visible range than in the infrared range, the reflection being nearly total and largely constant at a wavelength of roughly 1,200 nm and above.

Note that reflection R of solar cells 1 of this type, as shown in FIG. 1, and its reflectivity illustrated by way of example in FIG. 2, may be implemented by a separate reflective layer 12, provided toward the back between photovoltaic layer 13 and supporting layer 11, or by an internal reflective layer within the active photovoltaic layer.

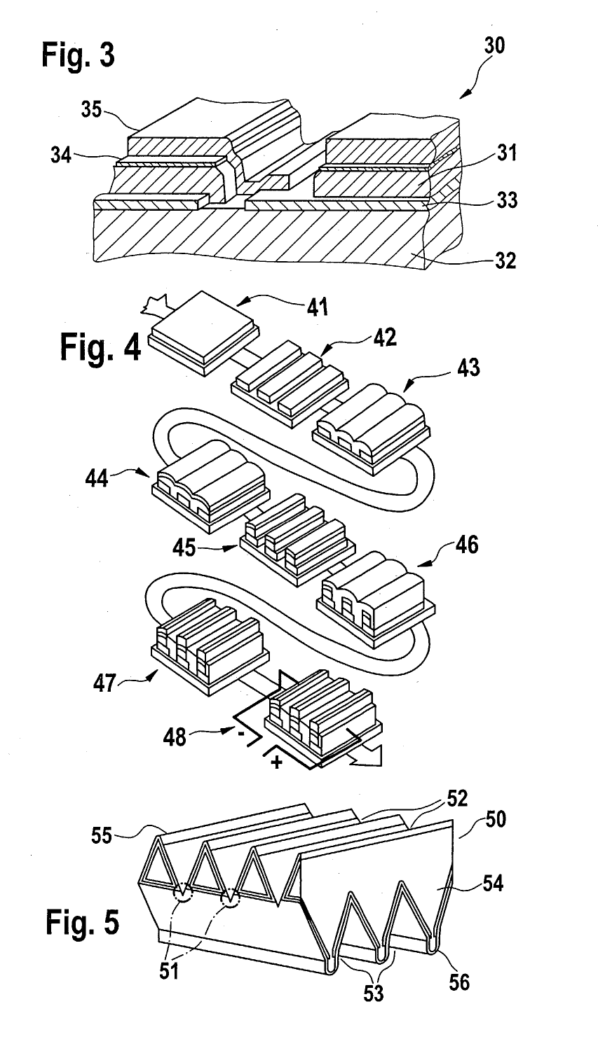

A second implementation of the device according to the present invention is explained on the basis of a CIS thin-film solar cell 30, illustrated schematically in FIG. 3, in which thin-film solar cells 30 are generally provided as the solar cells, and these thin-film solar cells 30 are integratively deposited and produced on suitable supporting layers or directly on vehicle body parts, in particular, on the vehicle roof. FIG. 3 shows, by way of example, a cross-sectional representation of the structure of CIS thin-film solar cell 30 on a suitable vehicle body part, which, according to the second embodiment of the present invention, may also be a vehicle body sheet 32, for example, the roof sheet of a motor vehicle. A roughly 0.5 μm molybdenum layer is applied to body sheet 32 serving as the supporting layer for the purpose of electrical contacting. Above it is a roughly 2 μm photovoltaically active absorber layer 31, which contains copper, indium and diselenide. Above active photovoltaic layer 31 is a roughly 0.05 μm CdS intermediate layer 34, above which is a roughly 1 μm ZnO contacting layer for the purpose of front contacting. This solar cell 30 may then be provided with a final protective layer (not illustrated in FIG. 3), which is visually coordinated with the vehicle paintwork. It goes without saying thai the shading and electrical properties of thin-film solar cell 30 are not significantly impaired thereby.

For clarification purposes, the production steps involved in manufacturing CIS thin-film solar cells are explained on the basis of the schematic representation in FIG. 4. In step 41, a roughly 0.5 μm molybdenum layer that acts as an electrical back contact is deposited by cathode sputtering onto a supporting substrate. In step 42, the back contact is patterned by laser treatment. In step 43, the photovoltaically active absorber layer, made of Cu(In,Ga)Se₂ and measuring about 2 μm thick, is applied by simultaneous vaporization. In step 44, a roughly 0.05 μm CdS intermediate layer is applied, for example, in a chemical immersion bath. In step 45, the photovoltaically active absorber layer is mechanically patterned. In step 46, a roughly 1 μm ZnO layer is deposited by cathode sputtering to form the electrical front contact. In step 47, the front contact is mechanically patterned. In step 48, the electrical end contacts are finally applied, and the unit is sealed.

The second implementation of the present invention, described on the basis of the CIS thin-film solar cells, allows these solar cells to be integrated into suitable vehicle body parts, for example, the vehicle roof, both to shade the underlying areas and to simultaneously generate power. Among the advantages of thin-film solar cells are the ability to continually reduce the amount of material needed and thus continually lower costs. In contrast to conventional silicon solar cells, the production process is easily automated. According to the present invention, the molybdenum layer provided for contacting purposes may be applied directly to a vehicle body part instead of to glass. As described above, the solar cells are further built up on this layer. This makes it possible to integrate the solar cell directly into, for example, the vehicle roof, and easily automate the direct production of solar cells. Finally, the thin-film solar cells produced in this manner, not limited to CIS thin-film solar cells, the term CIS representing the elements of copper, indium and selenium, are protected against environmental influences by a protective paint layer that is visually coordinated with the vehicle body part. Because the thin-film solar cells are only a few μm thick, they are easily integratable into the vehicle design and paintwork.

According to a third implementation of the principle object of the present invention, transparent solar cells are used as the solar cells. According to an advantageous embodiment, the transparent solar cefls may be embedded in glass. It is also possible and very advantageous to provide the transparent solar cells on vehicle windows or to integrate them into a window by providing them between two window panes. According to a further suitable application, which provides special shading of the vehicle interior, the transparent solar cells are attached to side windows and/or rear windows and/or the upper area of the windshield, in particular, to the inside thereof.

An embodiment of a transparent solar cell 50 is described on the basis of FIG. 5. To implement the present invention, therefore, a POWER solar cell 50 is advantageously provided, the term POWER representing Polycrystalline Wafer Engineering Result. Tiny holes 51 are incorporated into this POWER solar cell 50 by machining the base material, in particular, silicon, making the solar cell transparent. Holes 51 are produced at the intersections between intersecting, partially deeply penetrating, and more or less V-shaped grooves 52 and 53. The grooves are produced by mechanical milling using a diamond-tipped, rapidly rotating metal roller of the appropriate shape, which passes over silicon semiconductor block 54 at a suitable feed rate in the direction of grooves 52 and 53, respectively. Front contact 55 is produced on the top combs of the webs between grooves 52, and back contact 56 is produced on the bottom combs of the webs between grooves 53. No other necessary or suitable measures for producing transparent solar cells 50 of this type need to be described here to illustrate the purpose and objective of the present invention.

POWER solar cells of this type are manufactured, for example, by sunways AG, Macairestr. 5, 78467 Constance, Germany, and are described in greater detail in a company brochure. They are designed as a module having outer dimensions of 10×10 cm and are roughly 330 μm thick. The transparency is around 20%, but may be varied. These transparent solar cells may therefore be suitably deposited in the manner described above according to the present invention in thin layers as separate components to motor vehicle windows as shading and power-generating solar cells. Visually, they produce the effect of tinted window panes.

The device according to the present invention has the general advantage that solar cells provide shade for important motor vehicle parts, thus lowering the temperature to which they are exposed while simultaneously generating power that is supplied to the vehicle electrical system, i.e., the battery. This is possible, in particular, while the vehicle is at a standstill so that power is generated in the presence of sunlight or daylight and heating up of the vehicle is also reduced. As required, the energy that the air conditioning system requires to cool the vehicle may also be thereby reduced. To achieve these advantages, three different implementation examples are described, which, for their own part, are suitable and advantageous embodiments and refinements.

What is claimed is:

1. A device for generating power and providing shade in motor vehicles,
wherein solar cells (1, 30, 50) are provided as separate or integrated components on suitable vehicle body parts (2, 32) and are connected to loads, i.e., the vehicle battery, for the purpose of supplying the generated electrical power.

2. The device as recited in claim 1,
wherein solar cells (1) having a reflective back surface layer (12) or an internal reflective layer are provided as solar cells.

3. The device as recited in claim 2,
wherein the solar cells (1) having a reflective back surface layer or an internal reflective layer are designed as semiconductor, in particular, silicon semiconductor solar cells.

4. The device as recited in claim 2 or 3,
wherein the solar cells (1) are provided on a supporting layer (11); and the supporting layer (11) is permanently connected to a suitable vehicle body part, in particular, to the vehicle roof (2).

5. The device as recited in claim 4,
wherein the supporting layer (11) of the solar cells (1) is rigid or flexible.

6. The device as recited in claim 1,
wherein thin-film solar cells (30) are provided as solar cells; and these thin-film solar cells (30) are integratively deposited and produced on suitable supporting layers or directly on vehicle body parts, in particular, on the vehicle roof (32).

7. The device as recited in claim 6,
wherein the thin-film solar cell (30) is designed as a CIS solar cell, the term CIS representing the elements copper, indium and selenium from which the photovoltaically active absorber layer (31) is made.

8. The device as recited in claim 6 or 7,
wherein the thin-film solar cells (30) are provided with a protective layer that is visually coordinated with the vehicle paintwork.

9. The device as recited in claim 1,
wherein transparent solar cells (50) are provided as solar cells.

10. The device as recited in claim 9,
wherein the transparent solar cells (50) are embedded in glass.

11. The device as recited in claim 9 or 10,
wherein the transparent solar cells (50) are provided on windows of the vehicle or integrated into a window by providing them between two window panes.

12. The device as recited in claim 9, 10 or 11,
wherein the transparent solar cells (50) are attached to side windows and/or rear windows and/or the upper area of the windshield, in particular, to the inside thereof.

13. The device as recited in one of claims 9 through 12,
wherein POWER solar cells (POWER stands for Polycrystalline Wafer Engineering Result) are provided as transparent solar cells (50) into which tiny holes (51) are incorporated by machining the base material (54), in particular, silicon, making the solar cells (50) transparent.
